(19) United States
(12) Patent Application Publication
(10) Pub. No.: US 2006/0131726 A1
(43) Pub. Date: Jun. 22, 2006

(54) Arrangement of input/output pads on an integrated circuit

(76) Inventor: Thomas P. Bruch, Corvallis, OR (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/021,076

(22) Filed: Dec. 22, 2004

(51) Int. Cl. H01L 23/52

(52) U.S. Cl. 257/691

(57) ABSTRACT

Input/output pads are arranged on an integrated circuit. Input/output pads are placed around a perimeter of core circuitry. Each input/output pad has an input/output pad bond opening with a height in a direction perpendicular to the perimeter of the core circuitry and with a width in a direction parallel to the perimeter of the core circuit. A first group of the input/output pad bond openings is placed at a first distance from the core circuitry. Height for the input/output pad bond openings within the first group is greater than width for the input/output pad bond openings within the first group. A second group of the input/output pad bond openings is placed at a second distance from the core circuitry. Height for the input/output pad bond openings within the second group is less than width for the input/output pad bond openings within the second group.

### BACKGROUND

For an integrated circuit (IC) die that is to be placed in a wire-bond package, the size and shape of the input/output (I/O) pads on the die have a large effect on the overall size (and thus cost) of the die. For wire-bond packages, I/O pads include the sites where wires are bonded to the IC die and include circuitry needed to interface between core circuitry and external entities. For example, the I/O pads include wire-bond openings that are typically arranged in a ring around the perimeter of the core circuitry located in a center portion of the integrated circuit die. A typical IC requires a variety of types of interface circuits in order to accommodate various voltage levels and signaling protocols. The set of available I/O pad types is commonly called a pad library. When designing a pad library, a common form factor or “template” is defined so that I/O pads can be easily and efficiently arranged in a uniform fashion and so that shared signals that are made between adjacent I/O pads (such as power busses) can be connected by abutment. The optimum form factor (size and shape) of the I/O pads depends on the number of I/O pads needed for a particular IC relative to the size of the core circuitry for that IC.

Typically I/O pads are arranged on the IC die in a configuration that is either “in-line” or “staggered”. When arranged in an inline configuration, I/O pads are aligned in a single row parallel to the perimeter of core circuitry for the I/O die. When arranged in a staggered configuration, I/O pad bond openings are aligned in two rows parallel to the perimeter of core circuitry for the IC die. The form factor for in-line I/O pads is shorter than the form factor for staggered I/O pads, where height is measured perpendicular to the perimeter of core circuitry for the IC die. However, using staggered I/O pads, more I/O pads can be fit into a smaller width than for in-line I/O pads, where width is measured parallel to the perimeter of core circuitry for the IC die.

When the core logic perimeter is long enough so that there is enough room to fit all the needed I/O pads around the core logic perimeter, an IC die is said to be core-limited. When an IC die requires more I/O pads than can fit in a single layer around the perimeter of the core circuitry, an IC is said to be pad limited. It is generally desirable to avoid becoming pad limited. For a given core size, the number of I/O pads at which an IC becomes pad limited is much higher with staggered I/O pads than it is with in-line I/O pads. So, staggered I/O pads are preferred in cases where the number of I/O pads is relatively high. However, since staggered pads require the outer edge of the die to be farther from the core circuitry, there is an area penalty associated with their use in cases where the number of I/O pads is relatively low. So, in-line pads are preferred in cases where the number of I/O pads is relatively low.

To increase versatility, an integrated circuit manufacturer can create both an in-line I/O pad version and a staggered I/O pad version of each type of I/O pad. One disadvantage with this is that very different physical layouts are needed for these two versions, even when circuit schematics for both versions are identical. This introduces risk of functional or reliability problems. In order to address this risk, both versions of each I/O pad type often need to be implemented and tested before being used commercially. This is expensive and time consuming. With signals on I/O pads operating at high frequencies, the risk of introducing problems with a layout change is substantial.

Another disadvantage to offering pad libraries with both in-line and staggered configurations is that, as the number of I/O pads increases for a given core logic size, there is a significant range where neither the in-line nor the staggered pad configurations give an optimal die size. This range is between the point at which an IC becomes pad limited using in-line pads and the point at which it becomes pad-limited using staggered pads.

### SUMMARY OF THE INVENTION

In accordance with an embodiment of the present invention, input/output pads are arranged on an integrated circuit. Input/output pads are placed around a perimeter of core circuitry. Each input/output pad has an input/output pad bond opening with a height in a direction perpendicular to the perimeter of the core circuitry and with a width in a direction parallel to the perimeter of the core circuit. A first group of the input/output pad bond openings is placed at a first distance from the core circuitry. Height for the input/output pad bond openings within the first group is greater than width for the input/output pad bond openings within the first group. A second group of the input/output pad bond openings is placed at a second distance from the core circuitry. Height for the input/output pad bond openings within the second group is less than width for the input/output pad bond openings within the second group.

### BRIEF DESCRIPTION OF THE DRAWINGS

FIG. 1 is a simplified diagram illustrating location of I/O pads on an integrated circuit.

FIG. 2 is a simplified diagram illustrating an in-line configuration of I/O pads.

FIG. 3 is a simplified diagram illustrating a staggered configuration of I/O pads.

FIG. 4 is a simplified diagram illustrating a configuration of I/O pads in accordance with an embodiment of the present invention.

FIG. 5 is a simplified diagram illustrating another configuration of I/O pads in accordance with another embodiment of the present invention.

FIG. 6 is a simplified diagram illustrating another configuration of I/O pads in accordance with another embodiment of the present invention.

### DESCRIPTION OF THE EMBODIMENT

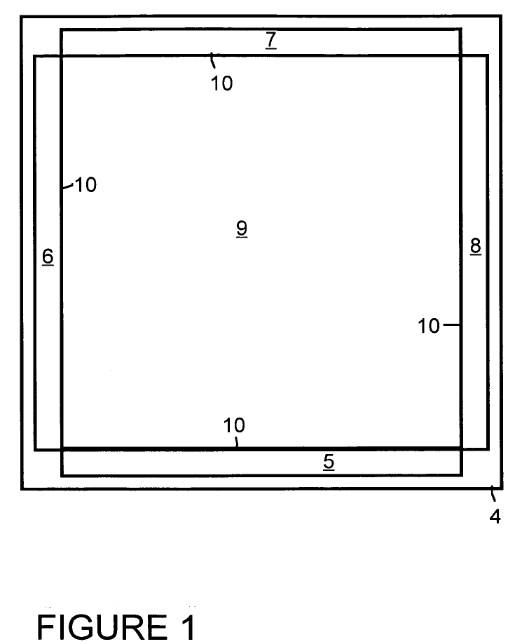

FIG. 1 shows an integrated circuit die 4. Core circuitry 9 has a perimeter 10. Around perimeter 10, I/O pads may be located, for example, in a region 5, a region 6, a region 7 and a region 8.

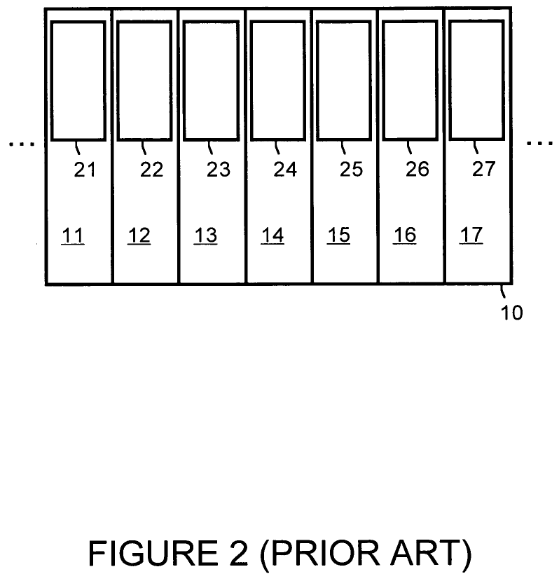

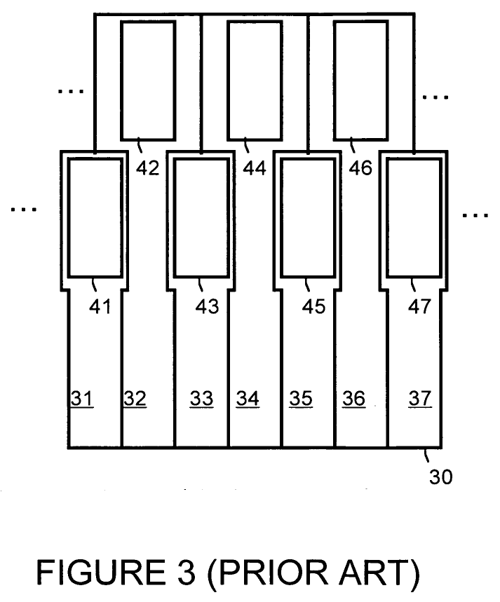

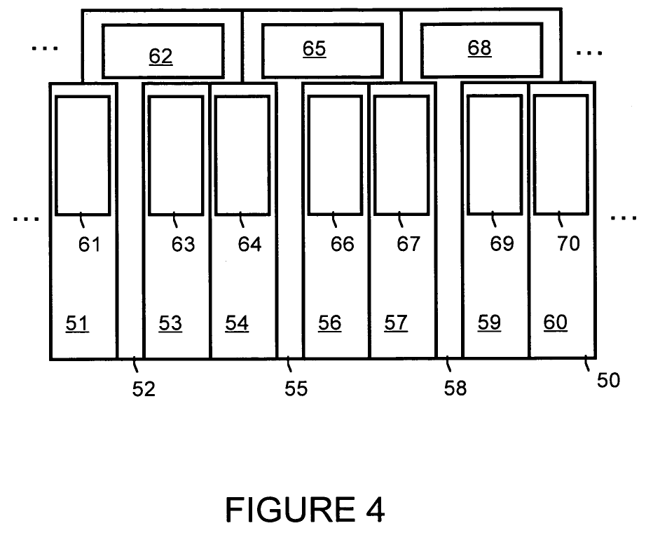

FIG. 2 is a simplified diagram illustrating an in-line configuration of I/O pads. A first I/O pad includes an I/O pad bond opening 21 and a region 11. Region 11 contains circuitry that interfaces between core circuitry 9 and entities outside integrated circuit die 4. A second I/O pad includes an I/O pad bond opening 22 and a region 12. Region 12 contains circuitry that interfaces between core circuitry 9 and entities outside integrated circuit die 4. A third I/O pad includes an I/O pad bond opening 23 and a region 13. Region 13 contains circuitry that interfaces between core circuitry 9 and entities outside integrated circuit die 4. A fourth I/O pad includes an I/O pad bond opening 24 and a region 14. Region 14 contains circuitry that interfaces between core circuitry 9 and entities outside integrated circuit die 4. A fifth I/O pad includes an I/O pad bond opening 25 and a region 15. Region 15 contains circuitry that interfaces between core circuitry 9 and entities outside integrated circuit die 4. A sixth I/O pad includes an I/O pad bond opening 26 and a region 16. Region 16 contains circuitry that interfaces between core circuitry 9 and entities outside integrated circuit die 4. A seventh I/O pad includes an I/O pad bond opening 27 and a region 17. Region 17 contains circuitry that interfaces between core circuitry 9 and entities outside integrated circuit die 4. The I/O pads shown in FIG. 2 are representative of I/O pads arranged around the entire perimeter 10 of core circuitry 9. FIG. 3 is a simplified diagram illustrating a staggered configuration of I/O pads. A first I/O pad includes an I/O pad bond opening 41 and a region 31. Region 31 contains circuitry that interfaces between core circuitry 9 and entities outside integrated circuit die 4. A second I/O pad includes an I/O pad bond opening 42 and a region 32. Region 32 contains circuitry that interfaces between core circuitry 9 and entities outside integrated circuit die 4. A third I/O pad includes an I/O pad bond opening 43 and a region 33. Region 33 contains circuitry that interfaces between core circuitry 9 and entities outside integrated circuit die 4. A fourth I/O pad includes an I/O pad bond opening 44 and a region 34. Region 34 contains circuitry that interfaces between core circuitry 9 and entities outside integrated circuit die 4. A fifth I/O pad includes an I/O pad bond opening 45 and a region 35. Region 35 contains circuitry that interfaces between core circuitry 9 and entities outside integrated circuit die 4. A sixth I/O pad includes an I/O pad bond opening 46 and a region 36. Region 36 contains circuitry that interfaces between core circuitry 9 and entities outside integrated circuit die 4. A seventh 1/0 pad includes an I/O pad bond opening 47 and a region 37. Region 37 contains circuitry that interfaces between core circuitry 9 and entities outside integrated circuit die 4. The I/O pads shown in FIG. 4 are representative of I/O pads arranged around the entire perimeter 30 of core circuitry 9.

FIG. 4 is a simplified diagram illustrating a configuration of I/O pads in accordance with an embodiment of the present invention. An I/O pad includes an I/O pad bond opening 61 and a region 51. Region 51 includes, for example, metal connectors, electrostatic discharge (ESD) protection circuitry and usually other interface circuitry. Height, in a direction perpendicular to perimeter 10, of I/O pad bond opening 61 is greater than width, in a direction parallel to perimeter 10, of I/O pad bond opening 61.

Another I/O pad includes an I/O pad bond opening 62 and a region 52. Region 52 includes, for example, metal connectors, electrostatic discharge (ESD) protection circuitry and usually other interface circuitry. I/O pad bond opening 62 is a wire bond opening within connection region 52. Height, in a direction perpendicular to perimeter 10, of I/O pad bond opening 62 is less than width, in a direction parallel to perimeter 10, of I/O pad bond opening 62.

Another I/O pad includes an I/O pad bond opening 63 and a region 53. Height, in a direction perpendicular to perimeter 10, of I/O pad bond opening 63 is greater than width, in a direction parallel to perimeter 10, of I/O pad bond opening 63. Another I/O pad includes an I/O pad bond opening 64 and a region 54. Height, in a direction perpendicular to perimeter 10, of I/O pad bond opening 64 is greater than width, in a direction parallel to perimeter 10, of I/O pad bond opening 64. Another I/O pad includes an I/O pad bond opening 65 and a region 55. Height, in a direction perpendicular to perimeter 10, of I/O pad bond opening 65 is shorter than width, in a direction parallel to perimeter 10, of I/O pad bond opening 65. Another I/O pad includes an I/O pad bond opening 66 and a region 56. Height, in a direction perpendicular to perimeter 10, of I/O pad bond opening 66 is greater than width, in a direction parallel to perimeter 10, of I/O pad bond opening 66.

Another I/O pad includes an I/O pad bond opening 67 and a region 57. Height, in a direction perpendicular to perimeter 10, of I/O pad bond opening 67 is greater than width, in a direction parallel to perimeter 10, of I/O pad bond opening 67. Another I/O pad includes an I/O pad bond opening 68 and a region 58. Height, in a direction perpendicular to perimeter 10, of I/O pad bond opening 68 is less than width, in a direction parallel to perimeter 10, of I/O pad bond opening 68. Another I/O pad includes an I/O pad bond opening 69 and a region 59. Height, in a direction perpendicular to perimeter 10, of I/O pad bond opening 69 is greater than width, in a direction parallel to perimeter 10, of I/O pad bond opening 69. Another I/O pad includes an I/O pad bond opening 70 and a region 60. Height, in a direction perpendicular to perimeter 10, of I/O pad bond opening 70 is greater than width, in a direction parallel to perimeter 10, of I/O pad bond opening 70.

The rectangular shape of I/O pad bond openings 61 through 70 allows room for both a wire bond site and a wafer probe site on each I/O pad bond opening. The wire bond site for I/O pad bond opening 62 would typically be centered halfway between the wire bond sites for wire pad bond openings 61 and 63 in the direction parallel to the perimeter of the core circuitry 10, just as for staggered wire bond sites. However, the wafer probe site for I/O pad bond opening 62 would typically not be centered between the wafer probe sites for I/O pad bond openings 61 and 63. I/O pad bond openings 61 through 70 are representative of I/O pad bond openings arranged around the entire perimeter 10 of the core circuitry 9. The dimensions of I/O pad bond openings vary depending on, for example, integrated circuit process technology, wire bonding technology, wafer type, and so on. For example, I/O pad bond openings 61, 63, 64, 66, 67, 69, and 70 have the same form factor as in-line I/O pad bond sites, such as those shown in FIG. 2. The average width per I/O pad is less than the average width per I/O pad of the in-line I/O pads shown in FIG. 2, but is greater than the average width per I/O pad of the staggered I/O pads shown in FIG. 3. The overall combined height of regions 51 and 52 shown in FIG. 4 is less than the overall combined height of staggered I/O pad regions 31 and 32 shown in FIG. 3, but is greater than the height of in-line I/O pad region 11 shown in FIG. 2. The center-to-center spacing of I/O pad bond openings 63 and 64 is less than the center-to-center spacing of I/O pad bond openings 62 and 65.

I/O pads that are used for relatively complex input/output signal are referred to as complex pads. I/O pads that are used for relatively simple signals, such as power and ground, are referred to as simple pads.

For example, in the configuration of I/O pads shown in FIG. 4, inner I/O pads, such as the I/O pads that include I/O pad bond opening 61, I/O pad bond opening, 63, I/O pad bond opening 64, I/O pad bond opening 66, 1/0 pad bond opening 67, I/O pad bond opening 69 and I/O pad bond opening 70, which are closer to perimeter 10, are used as complex pads. The complex pads include, for example, pads that require connections to adjacent pads, such as for pad-ring power busses, as well as connections to the core circuitry 9 through complex interface circuitry. Likewise, for example, outer I/O pads, such as I/O pads that include I/O pad bond opening 62, I/O pad bond opening 65 and I/O pad bond opening 68, which are farther from perimeter 10, are typically used as simple pads. One reason for this preference is that the inner I/O pads such as those that contain I/O pad bond openings 61, 63, 64, 66, 67, 69, and 70 have better provision for complex multiple connections to the core circuitry, since the width is greater at the point where these I/O pads abut the core circuitry. Also, having a single form factor (in-line) for complex pads reduces development effort and risk. Also, there are typically fewer simple pads such as power and ground than there are complex pads.

Depending on the needs of a particular circuit, around some of the perimeter of the core circuitry 9 some of the I/O pads can be configured in a “T” shape, as shown in FIG. 4, and some of the I/O pads can be configured in-line, as shown in FIG. 2. For example, in regions 5 and 7 (shown in FIG. 1) I/O pads can be in an in-line configuration, while in regions 6 and 8, I/O pads can be in a “T” configuration. Similarly, for example, in regions 5 and 7 (shown in FIG. 1) 1/0 pads can be in a “T” configuration, while in regions 6 and 8, I/O pads can be in a staggered configuration. And so on.

The ratio of inner I/O pads to outer I/O pads can vary depending upon the application, size of I/O pads, and so on. The ratio can even vary for different locations on the same integrated circuit, if desired. For the configuration shown in FIG. 4, the ratio of inner I/O pads to outer I/O pads is 2:1 when both inner and outer groups are fully populated. There is, however, no requirement that either the inner or outer group be fully populated. In order to meet wire bonding rules, for example, it is often necessary to have reduced bond site density near the corners of the integrated circuit. Spacer pads with no bond sites can be used to decrease density in either the inner or outer group. Likewise, another implementation can have wider outer I/O pads such that the ratio of inner to outer I/O pads is 3:1 when both inner and outer groups are fully populated. Or there could be a mixture of multiple different widths of outer I/O pads.

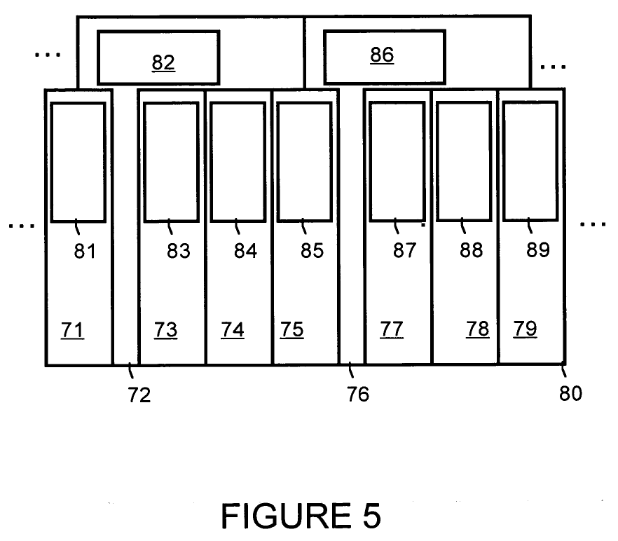

FIG. 5, for example, shows another configuration of I/O pads where the ratio of inner I/O pads to outer I/O pads is 3:1 when both inner and outer groups are fully populated.

In FIG. 5, an I/O pad includes an I/O pad bond opening 81 and a region 71. Height, in a direction perpendicular to perimeter 10, of I/O pad bond opening 81 is greater than width, in a direction parallel to perimeter 10, of I/O pad bond opening 81. Another I/O pad includes an I/O pad bond opening 82 and a region 72. Height, in a direction perpendicular to perimeter 10, of I/O pad bond opening 82 is less than width, in a direction parallel to perimeter 10, of I/O pad bond opening 82. Another I/O pad includes an I/O pad bond opening 83 and a region 73. Height, in a direction perpendicular to perimeter 10, of I/O pad bond opening 83 is greater than width, in a direction parallel to perimeter 10, of I/O pad bond opening 83. Another I/O pad includes an I/O pad bond opening 84 and a region 74. Height, in a direction perpendicular to perimeter 10, of I/O pad bond opening 84 is greater than width, in a direction parallel to perimeter 10, of I/O pad bond opening 84. Another I/O pad includes an I/O pad bond opening 85 and a region 75. Height, in a direction perpendicular to perimeter 10, of I/O pad bond opening 85 is greater than width, in a direction parallel to perimeter 10, of I/O pad bond opening 85.

Another I/O pad includes an I/O pad bond opening 86 and a region 76. Height, in a direction perpendicular to perimeter 10, of I/O pad bond opening 86 is less than width, in a direction parallel to perimeter 10, of I/O pad bond opening 86. Another I/O pad includes an I/O pad bond opening 87 and a region 77. Height, in a direction perpendicular to perimeter 10, of I/O pad bond opening 87 is greater than width, in a direction parallel to perimeter 10, of I/O pad bond opening 87. Another I/O pad includes an I/O pad bond opening 88 and a region 78. Height, in a direction perpendicular to perimeter 10, of I/O pad bond opening 88 is greater than width, in a direction parallel to perimeter 10, of I/O pad bond opening 88. Another I/O pad includes an I/O pad bond opening 89 and a region 79. Height, in a direction perpendicular to perimeter 10, of I/O pad bond opening 89 is greater than width, in a direction parallel to perimeter 10, of I/O pad bond opening 89.

I/O pads arranged in a “T” configuration have two groups of I/O pads. I/O pads with I/O pad bond openings that have a height, in a direction perpendicular to the perimeter of the core circuitry 9 that is greater than width, in a direction parallel to the perimeter can be referred to as, for example, the “first group” of I/O pads. Likewise, in a “T” configuration, I/O pads with I/O pad bond openings that have a height, in a direction perpendicular to the perimeter of the core circuitry 9 that is less than width, in a direction parallel to the perimeter can be referred to as, for example, the “second group” of I/O pads.

Generally, in the “T” configuration, it is preferred to place first group of I/O pads in an inner ring closer to the perimeter of the core circuitry 9, and second group of I/O pads in an outer ring farther from the perimeter. This is preferred, for example, because if the second group of I/O pads are used for power and ground signals, locating bond sites for the power and ground signals farthest from the perimeter of the core circuitry 9, and therefore closest to the die edge, helps to enable a less expensive two-layer package substrate to be used, and generally makes it easier to do the package substrate layout.

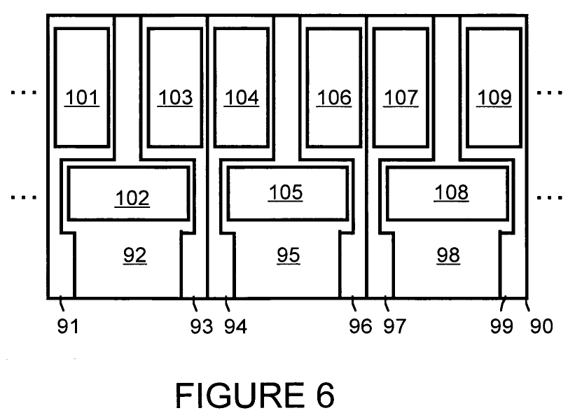

Nevertheless, there may arise some applications where it is preferred to place first group of I/O pads farther from the perimeter of the core circuitry 9, and second group of I/O pads closer to the perimeter. For example, FIG. 6 shows such a configuration.

In FIG. 6, an I/O pad includes an I/O pad bond opening 101 and a region 91. Height, in a direction perpendicular to perimeter 10, of I/O pad bond opening 101 is greater than width, in a direction parallel to perimeter 10, of I/O pad bond opening 101. Another I/O pad includes an I/O pad bond opening 102 and a region 92. Height, in a direction perpendicular to perimeter 10, of I/O pad bond opening 102 is less than width, in a direction parallel to perimeter 10, of I/O pad bond opening 102. Another I/O pad includes an I/O pad bond opening 103 and a region 93. Height, in a direction perpendicular to perimeter 10, of I/O pad bond opening 103 is greater than width, in a direction parallel to perimeter 10, of I/O pad bond opening 103. Another I/O pad includes an I/O pad bond opening 104 and a region 94. Height, in a direction perpendicular to perimeter 10, of I/O pad bond opening 104 is greater than width, in a direction parallel to perimeter 10, of I/O pad bond opening 104. Another I/O pad includes an I/O pad bond opening 105 and a region 95. Height, in a direction perpendicular to perimeter 10, of I/O pad bond opening 105 is less than width, in a direction parallel to perimeter 10, of I/O pad bond opening 105.

Another I/O pad includes an I/O pad bond opening 106 and a region 96. Height, in a direction perpendicular to perimeter 10, of I/O pad bond opening 106 is greater than width, in a direction parallel to perimeter 10, of I/O pad bond opening 106. Another I/O pad includes an I/O pad bond opening 107 and a region 97. Height, in a direction perpendicular to perimeter 10, of I/O pad bond opening 107 is greater than width, in a direction parallel to perimeter 10, of I/O pad bond opening 107. Another I/O pad includes an I/O pad bond opening 108 and a region 98. Height, in a direction perpendicular to perimeter 10, of I/O pad bond opening 108 is less than width, in a direction parallel to perimeter 10, of I/O pad bond opening 108. Another I/O pad includes an I/O pad bond opening 109 and a region 99. Height, in a direction perpendicular to perimeter 10, of I/O pad bond opening 109 is greater than width, in a direction parallel to perimeter 10, of I/O pad bond opening 109.

One disadvantage of the configuration shown in FIG. 6 is that neither of the two pad shapes can be used in a normal in-line configuration. Also, the very complex pad outlines can be very difficult to work with and may require a complicated set of rules regarding how the two shapes can and cannot be combined.

Use of a “T” configuration for I/O pad allows for more I/O pads to be utilized along a circuit periphery than are utilized in an in-line configuration. Also, use of a “T” configuration for I/O pad allows for a smaller distance between core circuitry 9 and die edges than is available when a staggered configuration is used. Thus use of a “T” configuration is often a good choice when the number of I/O pads desired for an integrated circuit is greater than can be achieved using an in-line configuration, but less than is provided by a staggered configuration. The “T” configuration can give significant area savings when compared to either in-line or staggered configurations in these cases.

The foregoing discussion discloses and describes merely exemplary methods and embodiments of the present invention. As will be understood by those familiar with the art, the invention may be embodied in other specific forms without departing from the spirit or essential characteristics thereof. Accordingly, the disclosure of the present invention is intended to be illustrative, but not limiting, of the scope of the invention, which is set forth in the following claims.

I claim:

1. An integrated circuit comprising:
core circuitry; and,
input/output pads arranged around a perimeter of the core circuitry, each input/output pad having an input/output pad bond opening with a height in a direction perpendicular to the perimeter of the core circuitry and with a width in a direction parallel to the perimeter of the core circuitry;
wherein the input/output pads are arranged so that a first group of the input/output pad bond openings are located at a first distance from the core circuitry and a second group of the input/output pad bond openings are located at a second distance from the core circuitry;
wherein height for the input/output pad bond openings within the first group is greater than width for the input/output pad bond openings within the first group; and,
wherein height for the input/output pad bond openings within the second group is less than width for the input/output pad bond openings within the second group.

2. An integrated circuit as in claim 1 wherein the second distance is greater than the first distance.

3. An integrated circuit as in claim 1 wherein the first distance is greater than the second distance.

4. An integrated circuit as in claim 1 wherein a ratio of number of fully populated input/output pad bond openings in the first group to number of fully populated input/output pad bond openings in the second group is 2:1.

5. An integrated circuit as in claim 1 wherein a ratio of number of fully populated input/output pad bond openings in the first group to number of fully populated input/output pad bond openings in the second group is 3:1.

6. An integrated circuit as in claim 1 wherein the input/output pads are additionally arranged so that a third group of input/output pad bond openings are in an in-line configuration.

7. An integrated circuit as in claim 1 wherein the input/output pads are additionally arranged so that a third group of input/output pad bond openings are in a staggered configuration.

8. A method for arranging input/output pads on an integrated circuit comprising:
placing input/output pad bond openings around a perimeter of core circuitry, each input/output pad bond opening having a height in a direction perpendicular to the perimeter of the core circuitry and having a width in a direction parallel to the perimeter of the core circuitry, including:
placing a first group of the input/output pad bond openings at a first distance from the core circuitry, so that height for the input/output pad bond openings within the first group is greater than width for the input/output pad bond openings within the first group, and
placing a second group of the input/output pad bond openings at a second distance from the core circuitry so that height for the input/output pad bond openings within the second group is less than width for the input/output pad bond openings within the second group.

9. A method as in claim 8 wherein the second distance is greater than the first distance.

10. A method as in claim 8 wherein the first distance is greater than the second distance.

11. A method as in claim 8 wherein a ratio of number of fully populated input/output pad bond openings in the first group to number of fully populated input/output pad bond openings in the second group is 2:1.

12. A method as in claim 8 wherein a ratio of number of fully populated input/output pad bond openings in the first group to number of fully populated input/output pad bond openings in the second group is 3:1.

13. A method as in claim 8 wherein the input/output pad bond openings are additionally placed so that a third group of input/output pad bond openings are in an in-line configuration.

14. A method as in claim 8 wherein the input/output pad bond openings are additionally placed so that placing a third group of input/output pad bond openings are in a staggered configuration.

15. An integrated circuit comprising:
input/output pads arranged in a configuration around a perimeter of the core circuitry, so that input/output pad bond openings are each rectangular in shape having a height in a direction perpendicular to the perimeter of the core circuitry and having a width in a direction parallel to the perimeter of the core circuitry;
wherein the input/output pads are arranged so that a first group of the input/output pad bond openings are located at a first distance from the core circuitry and a second group of the input/output pad bond openings are located at a second distance from the core circuitry;
wherein height for the input/output pad bond openings within the first group is greater than width for the input/output pad bond openings within the first group; and,
wherein height for the input/output pad bond openings within the second group is less than width for the input/output pad bond openings within the second group.

16. An integrated circuit as in claim 15 wherein the second distance is greater than the first distance.

17. An integrated circuit as in claim 15 wherein the first distance is greater than the second distance.

18. An integrated circuit as in claim 15 wherein a ratio of number of fully populated input/output pad bond openings in the first group to number of fully populated input/output pad bond openings in the second group is 2:1.

19. An integrated circuit as in claim 15 wherein the input/output pads are additionally arranged so that a third group of input/output pad bond openings are in an in-line configuration.

20. An integrated circuit as in claim 15 wherein the input/output pads are additionally arranged so that a third group of input/output pad bond openings are in a staggered configuration.
